(19) United States
(12) Patent Application Publication
(10) Pub. No.: US 2011/0121426 A1
(43) Pub. Date: May 26, 2011

(54) ELECTRONIC DEVICE WITH FUSE STRUCTURE AND METHOD FOR REPAIRING THE SAME

(76) Inventors: Ming-Sheng Yang, Hsinchu City (TW); Cheng-Feng Peng, Hsinchu County (TW); Jia-Fu Jhang, Miaoli County (TW)

(21) Appl. No.: 12/626,078

(22) Filed: Nov. 25, 2009

(51) Int. Cl. H01L 23/525; H01L 21/768

(52) U.S. Cl. 257/529; 438/4; 257/E23.149; 257/E21.592

(57) ABSTRACT

According to an embodiment of the invention, an electronic device with a fuse structure is provided. The electronic device includes a substrate, at least a conducting layer formed in or on the substrate and having a fuse area, and at least a lens disposed overlying the fuse area of the conducting layer, wherein the lens is substantially aligned with the fuse area and there is no optical device disposed between the lens and the fuse area.

### BACKGROUND OF THE INVENTION

1. Field of the Invention

The present invention relates to an electronic device with a fuse structure, and in particular relates to a method for repairing an electronic device with a fuse structure.

2. Description of the Related Art

Advances in semiconductor processing technologies are dramatically reducing the feature sizes of integrated circuit (IC) devices while increasing device packing density. Unfortunately, as the density of the IC devices increases and the number of discrete devices increases on the IC, fabrication yield for many IC devices (chip yield) decrease. For example, one IC device, wherein an increase in the number of discrete devices decreases fabrication yields, is the dynamic random access memory (DRAM).

One method used to hinder decrease in fabrication yield for RAM devices due to increase in discrete devices thereof, is to provide additional rows of memory cells and fuse each row by fuse structures. Currently laser light beams are used to open connections (breaking the fuse structures) in the RAM devices, such as in DRAM or SRAM devices, to disable defective rows of memory cells and to modify the address decoder so that spare rows of memory cells are selected instead.

Meanwhile, IC devices that have high packing density cannot, in general, be repaired or modified. There exists, however, a large class of ICs that are intended to be repairable and/or modifiable. In certain cases, no real circuit exits until the ICs has been personalized by breaking certain connections, thereby determining how the components are to be connected to one another. In this case, fuse structures may be formed between components. The fuse structures may be optionally removed by a laser light beam to repair and/or modify the IC devices.

However, using precise laser beams to repair and/or modify the IC devices increases fabrication costs due to special machinery and high power required for the laser beam process. In some cases, if the power of the laser light beam is too high, other components other than the fuse structures intended to be broken may also be broken. In addition, designing of large fuse structure layouts can occupy much chip area. Moreover, despite the special machinery, fabrication yield still decreases due to the high precision process.

Thus, an electronic device with a new fuse structure is desired to facilitate the laser repairing process.

### BRIEF SUMMARY OF THE INVENTION

According to an illustrative embodiment, an electronic device with a fuse structure is provided. The electronic device with a fuse structure includes a substrate, at least a conducting layer formed in or on the substrate and having a fuse area, and at least a lens disposed overlying the fuse area of the conducting layer, wherein the lens is substantially aligned with the fuse area and there is no optical device disposed between the lens and the fuse area.

According to an illustrative embodiment, an electronic device with a fuse structure is provided. The electronic device with a fuse structure includes a substrate, a plurality of conducting layers formed in or on the substrate and each having a fuse area, and a plurality lenses each disposed overlying one of the fuse areas of the conducting layers, wherein each of the lenses is substantially aligned with the respective fuse area and there is no optical device disposed between each of the lenses and the respective fuse area.

According to an illustrative embodiment, a method for repairing an electronic device with a fuse structure is provided. The method includes providing an electronic device including a substrate, a plurality of conducting layers formed in or on the substrate and each having a fuse area, and a plurality lenses each disposed overlying one of the fuse areas of the conducting layers, wherein each of the lenses is substantially aligned with the respective fuse area and there is no optical device disposed between each of the lenses and the respective fuse area. The method further includes irradiating one of the lenses by a light beam to remove at least a portion of the respective fuse area of the conducting layer under the respective lens.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A and 1B are a cross-sectional view and a top view of an electronic device with a fuse structure known by the inventors, respectively;

FIGS. 2A and 2B respectively show a cross-sectional view and a top view of an electronic device with a fuse structure according to an embodiment of the present invention;

FIG. 2C is an enlarged cross-sectional view of the electronic device shown in FIG. 2A;

FIGS. 3A and 3B respectively shows cross-sectional views of an electronic device with a fuse structure according to an embodiment of the present invention;

FIG. 3C is a top view of the electronic device shown in FIG. 3A or 3B;

FIGS. 4A and 4B are a cross-sectional view and a top view of an electronic device with a fuse structure according to an embodiment of the present invention; and

FIG. 5 is a cross-sectional view of an electronic device with a fuse structure according to an embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It is understood, that the following disclosure provides many difference embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer include embodiments where the first and second layers are in direct contact and those where one or more layers are interposing the first and second layers.

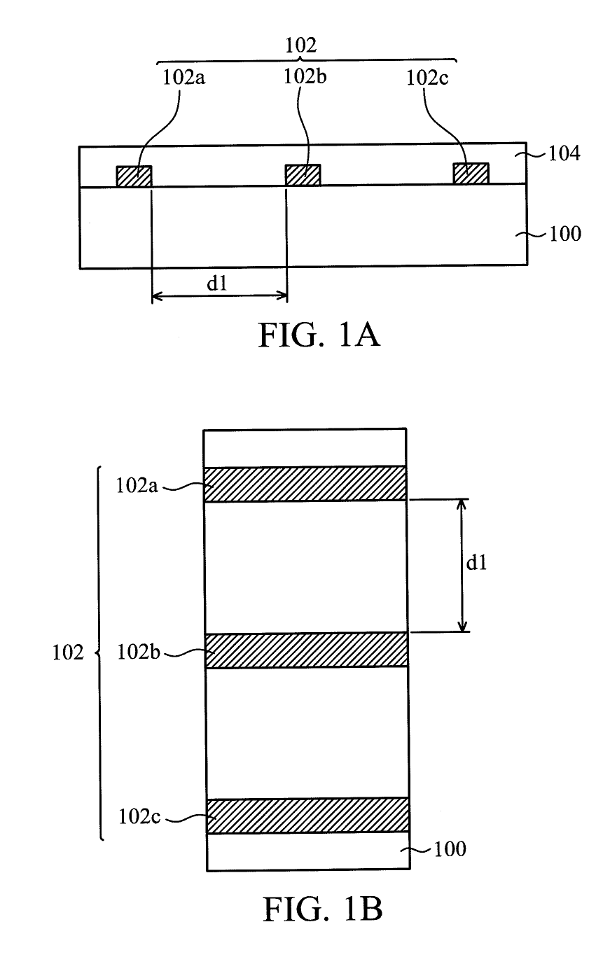

FIGS. 1A-1B demonstrate a cross-sectional view and a top view of an electronic device with a fuse structure known by the inventors, respectively, which show a problem with the electronic device with a fuse structure found by the inventor. As shown in FIG. 1A, an electronic device with a fuse structure is provided. The electronic device includes a plurality of conducting layers 102 formed between a substrate 100 and a passivation layer 104. Each of the conducting layers 102 has a fuse area, which may be irradiated by a laser light beam to be removed if needed. As shown in FIGS. 1A and 1B, three different fuse areas 102a, 102b, and 102c of three different conducting layers 102 which may be electrically insulated from each other are shown. Each of the fuse areas may be electrically connected to a specific component. When the integrated circuit of the electronic device requires modification or repair, a specific fuse area is removed or broken to open the electrical path between the specific fuse area and the specific component. For example, laser light beams may be used to open connections (breaking the fuse structures) in the RAMs, such as in DRAM or SRAM devices, to disable defective rows of memory cells and to modify the address decoder so that spare rows of memory cells are selected instead. However, due to the laser light beam having some degree of precision error and the spot size of the laser light beam, the distance d1 between two nearby fuse areas, such as the fuse areas 102a and 102b, must be about 4 μm to about 8 μm, to ensure that the laser light beam only cuts the desired fuse area. Thus, the conducting layers 102 including the fuse areas occupy a large chip area, hindering size reduction of the electronic device.

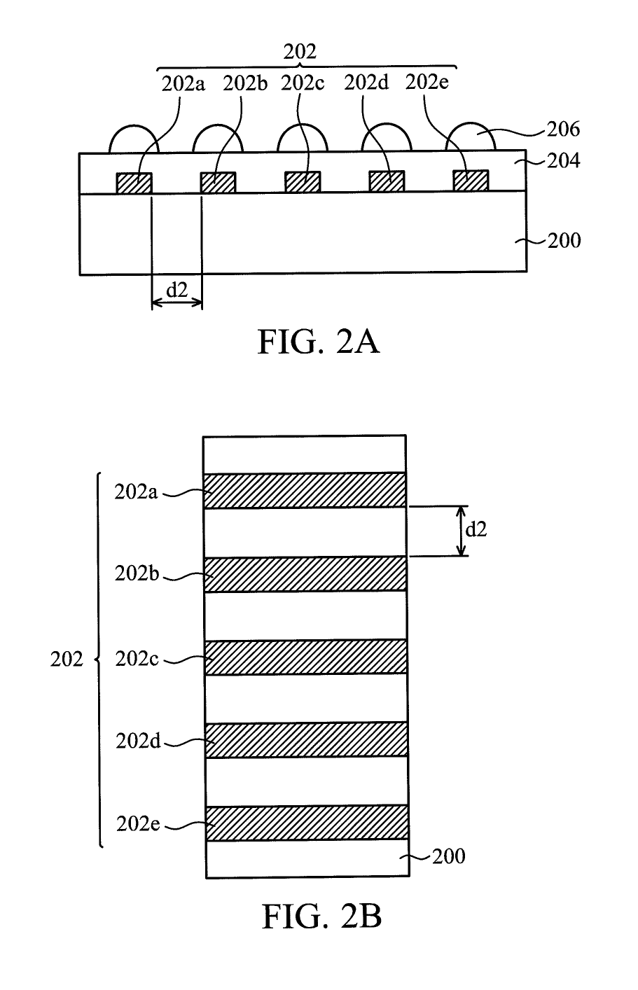

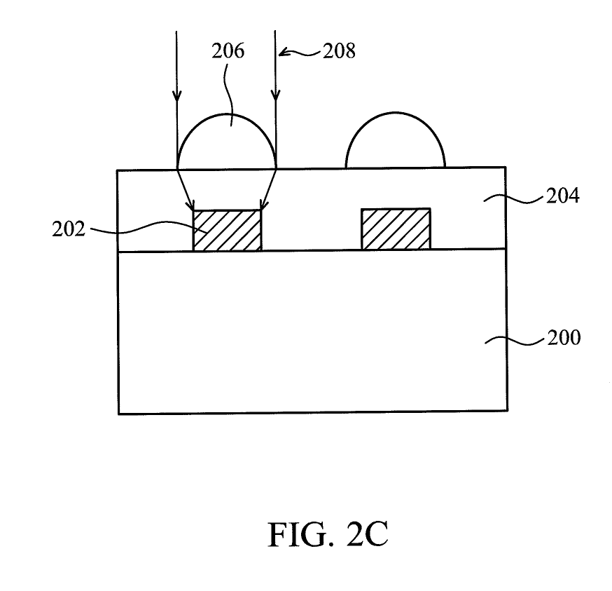

FIGS. 2A-2B respectively show a cross-sectional view and a top view of an electronic device with a fuse structure according to an embodiment of the present invention. FIG. 2C shows an enlarged cross-sectional view of the electronic device shown in FIG. 2A. As shown in FIGS. 2A and 2B, an electronic device with a fuse structure in accordance with an embodiment of the invention is provided. The electronic device includes a substrate 200. The substrate 200 may include, but is not limited to, a semiconductor substrate or an insulating substrate. In some cases, the substrate 200 may also include a plurality of semiconductor devices formed therein. For example, the substrate 200 may include, but is not limited to, a RAM device such as static random-access-memory (SRAM), dynamic random-access-memory (DRAM), magnetic random-access-memory (MRAM), non-volatile-memory (NVM), and/or combinations thereof. The NVM may further include programmable read-only-memory (PROM), phase-change-memory, and flash memory. The plurality of semiconductor devices may further include, but are not limited to, passive components such as resistors, capacitors, and inductors, active components such as metal-oxide-semiconductor field effect transistors (MOSFETs), bipolar transistors, high voltage transistors, high frequency transistors, or combinations thereof. The plurality of semiconductor devices may be isolated from each other by isolation features based on structures incorporating junction isolation, field isolation, and dielectric isolation such as local oxidation of silicon (LOCOS) and shallow trench isolation (STI). In another embodiment, the electronic device may include an LCD device or any other integrated circuit.

In the embodiment shown in FIGS. 2A and 2B, the electronic device includes at least a conducting layer 202 formed in or on the substrate 200. In this embodiment, a plurality of conducting layers 202 are formed on the substrate 200. The conducting layer 202 may include any kind of conducting material, such as a metal material, a semiconductor material, a conducting polymer material, a conducting oxide material, or combinations thereof. The conducting layer 202 is electrically connected to a specific component formed on and/or in the substrate 200. Each of the conducting layers 202 has a fuse area, such as the fuse areas 202a, 202b, 202c, 202d, and 202e shown in FIGS. 2A and 2B. When the circuit of the electronic device is needed to be modified or repaired, a specific fuse area is removed or broken to open the electrical path between the specific fuse area and the specific component.

As shown in FIG. 2A, at least a lens 206 is disposed overlying the fuse area of the conducting layer 202, wherein the lens 206 is substantially aligned with the fuse area and there is no optical device disposed between the lens 206 and the fuse area. In one embodiment, the lens 206 may include a microlens. The material of the lens 206 may include a transparent material, such as a transparent oxide, transparent polymer, or the like. The lens 206 may have a lens size ranging from about (but is not limited to) 1 μm to 10 μm, a lens height ranging from about (but is not limited to) 1 μm to 5 μm, an n value (refractive index) ranging from about 1 to 2, and a focus length ranging from about 1 μm to 10 μm. The optical device mentioned above may include, but is not limited to, an image sensor, a light emitting element, or the like. In the embodiment shown in FIG. 2A, there are a plurality of lenses 206 disposed overlying the substrate 200. Each of the lenses 206 is disposed on one of the fuse area of the conducting layers 202. Each of the lenses 206 is substantially aligned with a respective fuse area and there is no optical device disposed between each of the lenses 206 and the respective fuse area. A passivation layer 204 may be optionally formed between the lens 206 and the fuse area of the conducting layer 202. The passivation layer 204 may include, but is not limited to, an oxide, nitride, or combinations thereof. The lens 206 is used to focus a light beam such as a laser light beam onto a specific fuse area of the conducting layer 202 according to requirement. Thus, it is preferable that the passivation layer 206 between the lens 206 and the fuse area absorbs minimal laser light. Therefore, the material of the passivation layer 206 may be chosen accordingly.

As shown in FIG. 2C, when a specific fuse area of the conducting layer 202 is determined to be opened, a light beam 208 is directed to irradiate the specific lens 206 overlying the specific fuse area. For example, a test process of the electronic device may be optionally performed to determine which one of the lenses 206 and the fuse area of the conducting layer 202 thereunder are to be irradiated by the light beam 208. The lens 206 is designed to focus the light beam 208 onto the fuse area thereunder to remove at least a portion of the fuse area of the conducting layer 202. Thus, the energy of the light beam 208 needs to be strong enough to remove the fuse area of the conducting layer 202. Depending on different materials of the conducting layer 202, different light beam 208 sources may be adopted. In one embodiment, a laser light beam may be used as the light beam 208 to remove at least a portion of the fuse area of the conducting layer 202, thus modifying and/or repairing the circuit of the electronic device. For example, the laser light beam may have a laser energy ranging between 0.8 and 1.2 microjoules with a spot diameter of 5 microns and a pulse width of 35 ns. It should be appreciated, however, that the light source of the light beam 208 is not limited to laser light beams. In another embodiment, other light sources such as an ultraviolet light, x-ray light, or other suitable lights may be used, depending on requirement.

Because the light beam 208 is “focused” by the lens 206, the spot size of the light beam 208 can be significantly reduced. In this case, the distance d2 between nearby fuse areas of the conducting layers 202 may be also reduced, as shown in FIGS. 2A and 2B. For example, a distance d2 smaller than the distance d1 shown in FIG. 1 is satisfactory enough to ensure that the light beam 208 will only cut the desired fuse area. Thus, the conducting layers 102 including the fuse areas can occupy less chip area, as compared with that shown in FIG. 1, facilitating reduction in size of the electronic device. The precision of light beam 208 irradiation may also be improved since the lens 206 which may have a bigger size is now the “target” of the light beam 208. In addition, because the energy of the light beam 208 will also be focused onto the fuse area requiring removal, the cutting process of the fuse area may be performed at a faster speed, leading to higher fabrication yields. Since the energy of the light beam 208 is enhanced by focusing of the lens 206, a low-powered light beam 208 source will be satisfactory enough to modify and/or repair the circuits of the electronic device. Additionally, expensive machinery is not required.

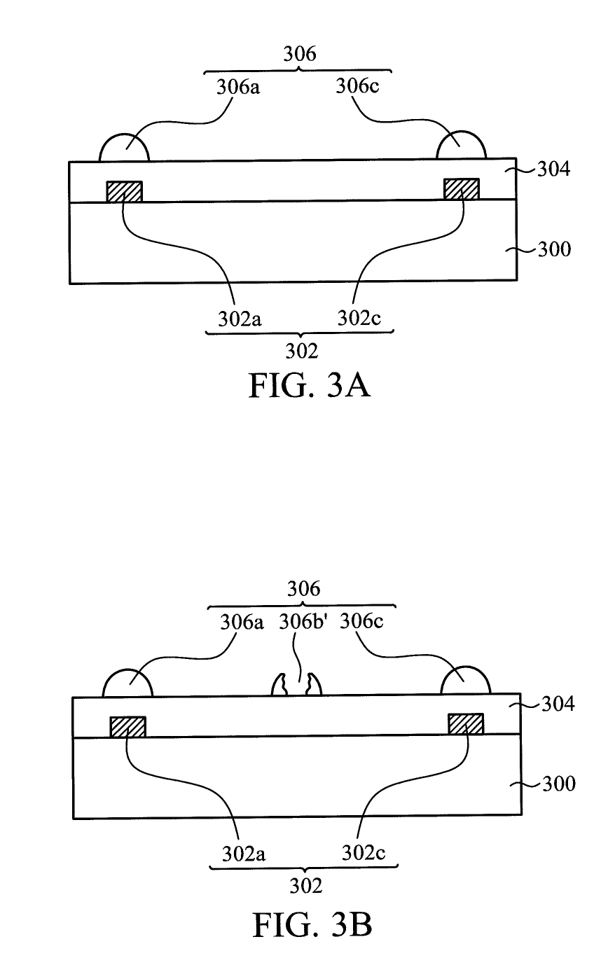

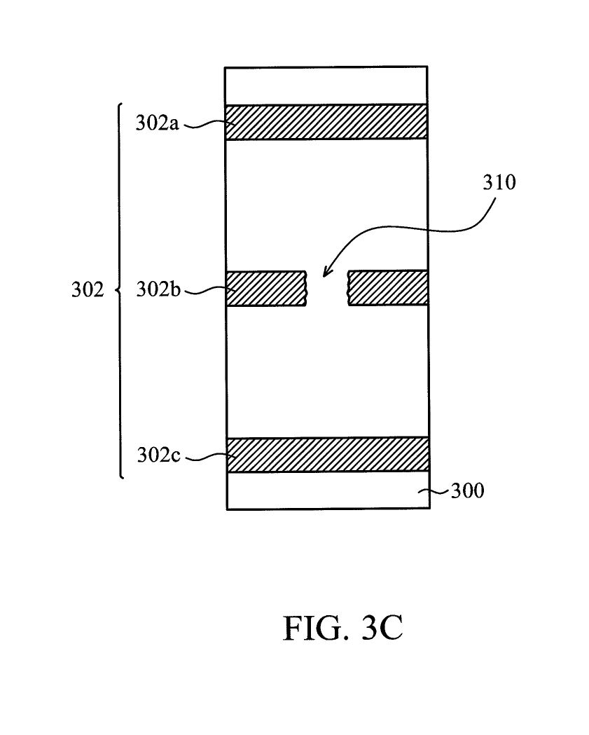

FIGS. 3A and 3B respectively shows cross-sectional views of an electronic device with a fuse structure according to an embodiment of the present invention. FIG. 3C shows a top view of the electronic device shown in FIG. 3A or 3B. In the embodiments shown in FIG. 3, one of the fuse areas of the conducting layers is opened (partially removed) to modify and/or repair the circuit of the electronic device. Referring to FIGS. 3A and 3C, three conducting layers 302 are formed between an optionally formed passivation layer 304 and a substrate 300. The conducting layers 302 each has fuse areas 302a, 302b, and 302c, respectively. A plurality of lenses 306 are disposed overlying the substrate 300. Each of the lenses 306, such as the lens 306a or 306c, is disposed overlying a respective fuse area of the conducting layer 302. Each of the lenses 306 is substantially aligned with a respective fuse area and there is no optical device disposed therebetween.

In one embodiment, it is determined that the conducting layer 302 having the fuse area 302b is to be opened to modify and/or repair the circuit of the electronic device. A light beam is directed to irradiate the lens on the fuse area 302b. Then, at least a portion of the fuse area 302b is removed. As shown in FIG. 3C, after a portion of the fuse area 302b is removed by the light beam, an opening 310 is formed in the fuse area 302b. In one embodiment, the opening 310 separates the conducting layer 302 having the fuse area 302b into a first portion (the left portion beside the opening 310) and a second portion (the right portion beside the opening 310) electrically insulated from the first portion.

After a portion of the fuse area 302b is removed by the light beam, the respective lens overlying the fuse area 302b may be partially or completely removed. Referring to FIG. 3A, the lens over the fuse area 302b is completely removed after the light beam is irradiated and only the lens 306a and 306c not irradiated by the light beam, remain on the fuse areas 302a and 302c, respectively. Referring to FIG. 3B, in another embodiment, the lens 306b′ overlying the fuse area 302b is at least partially broken after irradiation of the light beam. Whether the lens irradiated by the light beam is partially broken or completely broken (completely removed) may depend on the material of the lens and the energy of the light beam.

Although the lens of the electronic device with a fuse structure described above will be partially or completely removed (or broken) after irradiated by the light beam, the embodiment of the invention is not limited to a specific example. In another embodiment, the lens overlying a fuse area which is at least partially removed (or opened) by a light beam is completely remained.

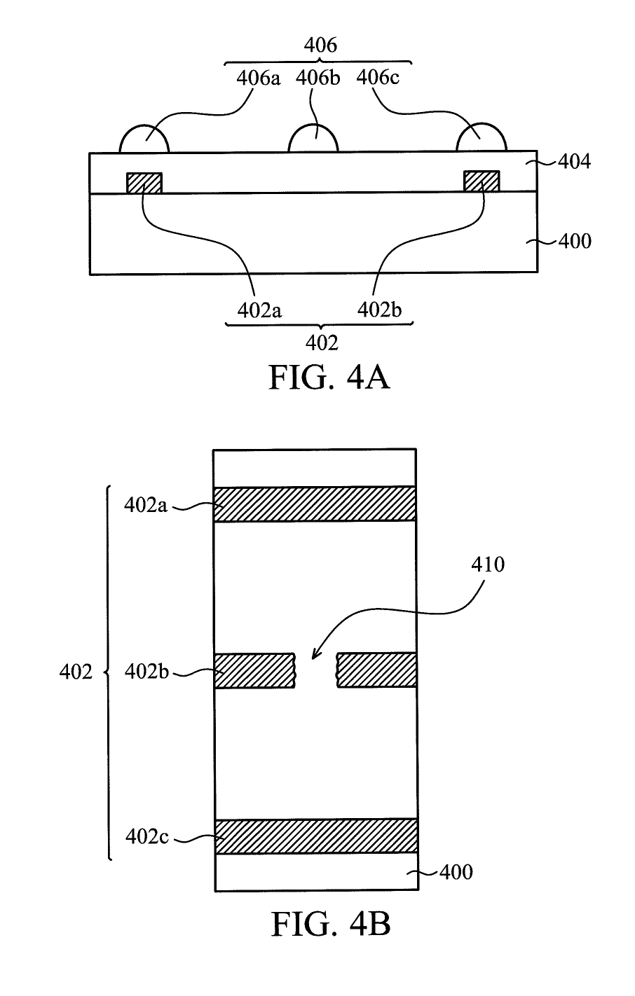

FIGS. 4A and 4B show a cross-sectional view and a top view of an electronic device with a fuse structure according to an embodiment of the present invention. In this embodiment, a plurality of conducting layers 402 are formed between an optionally formed passivation layer 404 and a substrate 400. A plurality of lenses 406 including lenses 406a, 406b, and 406c are disposed on the substrate 400. Each of the conducting layers 402 has a fuse area ready for removal by a light beam if needed, wherein each of the lenses is substantially aligned with a respective fuse area and there is no optical device disposed between each of the lenses and the respective fuse area.

Referring to FIGS. 4A and 4B, three fuse areas 402a, 402b, and 402c are shown, and it is determined that the fuse area 402b of the conducting layer 402 is to be at least partially removed by a light beam to modify and/or repair the circuit of the electronic device. A light beam, such as a laser light beam or other light beam with enough energy and suitable wavelength, is directed to irradiate the lens 406b. The light beam can be focused on a portion of the fuse area 402b and an opening 410 is therefore formed in the conducting layer 402 having the fuse area 402b. The opening 410 separates the respective conducting layer 402 into two electrically insulated portions, and thus the circuit of the electronic device is modified and/or repaired. In this case, the lens 402b is not damaged by the light beam. Thus, the lens 402b is still on the substrate 400.

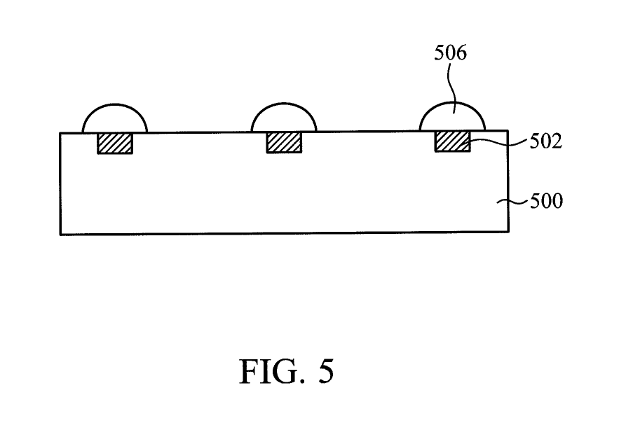

Although each of the electronic devices of the embodiments discussed above has a passivation layer formed between the fuse area of the conducting layer and the lens, the embodiment of the invention is not limited to specific examples. FIG. 5 shows a cross-sectional view of an electronic device with a fuse structure according to an embodiment of the present invention. In this embodiment, a plurality of conducting layers 502 each having a fuse area are formed in a substrate 500. A plurality of lenses 506 are disposed on the substrate 500. Each of the lenses 506 is disposed on one of the conducting layers 502. In this case, the lens 506 directly contacts with the fuse area of the conducting layer. No passivation layer is formed therebetween. A light beam can also be focused by the lens 506 onto the fuse area thereunder to open the conducting layer and modify and/or repair the circuit of the electronic device.

By disposing a lens between a fuse area of an electronic device and a light beam, repair or modification of a circuit of the electronic device may be efficiently performed. Additionally, the chip size and fuse layout pitch (pitch between nearby fuse areas) of an electronic device thereof may be reduced. In addition, the cost of special machinery for producing the laser beam may also be reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device with a fuse structure, comprising:
a substrate;
at least a conducting layer formed in or on the substrate and having a fuse area; and
at least a lens disposed overlying the fuse area of the conducting layer, wherein the lens is substantially aligned with the fuse area and there is no optical device disposed between the lens and the fuse area.

2. The electronic device with a fuse structure as claimed in claim 1, further comprising a passivation layer formed between the lens and the conducting layer.

3. The electronic device with a fuse structure as claimed in claim 1, further comprising an opening formed in the fuse area.

4. The electronic device with a fuse structure as claimed in claim 3, wherein the opening separates the conducting layer into a first portion and a second portion electrically insulated from the first portion.

5. The electronic device with a fuse structure as claimed in claim 3, wherein the lens overlying the opening is at least partially broken.

6. The electronic device with a fuse structure as claimed in claim 1, wherein the lens comprises a microlens.

7. The electronic device with a fuse structure as claimed in claim 1, wherein the lens directly contacts with the fuse area of the conducting layer.

8. The electronic device with a fuse structure as claimed in claim 1, wherein the electronic device comprises a RAM device.

9. An electronic device with a fuse structure, comprising:
a substrate;
a plurality of conducting layers formed in or on the substrate and each having a fuse area; and
a plurality of lenses each disposed overlying one of the fuse areas of the conducting layers, wherein each of the lenses is substantially aligned with the respective fuse area and there is no optical device disposed between each of the lenses and the respective fuse area.

10. The electronic device with a fuse structure as claimed in claim 9, further comprising at least an opening formed in at least one of the fuse areas.

11. The electronic device with a fuse structure as claimed in claim 10, wherein the opening separates the respective conducting layer into a first portion and a second portion electrically insulated from the first portion.

12. The electronic device with a fuse structure as claimed in claim 10, wherein the lens overlying the opening is at least partially broken.

13. A method for repairing an electronic device with a fuse structure, comprising:
providing an electronic device comprising:
a substrate;
a plurality of conducting layers formed in or on the substrate and each having a fuse area; and
a plurality of lenses each disposed overlying one of the fuse areas of the conducting layers, wherein each of the lenses is substantially aligned with the respective fuse area and there is no optical device disposed between each of the lenses and the respective fuse area; and
irradiating one of the lenses by a light beam to remove at least a portion of the respective fuse area of the conducting layer under the respective lens.

14. The method for repairing an electronic device with a fuse structure as claimed in claim 13, wherein the light beam comprises a laser light beam.

15. The method for repairing an electronic device with a fuse structure as claimed in claim 13, wherein after the portion of the respective fuse area is removed by the light beam, the respective conducting layer is separated into a first portion and a second portion electrically insulated from the first portion.

16. The method for repairing an electronic device with a fuse structure as claimed in claim 13, wherein after the portion of the respective fuse area is removed by the light beam, the respective lens is partially or completely removed.

17. The method for repairing an electronic device with a fuse structure as claimed in claim 13, further comprising a test process of the electronic device to determine which one of the lenses is irradiated by the light beam.

18. The method for repairing an electronic device with a fuse structure as claimed in claim 13, wherein the lenses comprise a microlens.

19. The method for repairing an electronic device with a fuse structure as claimed in claim 13, wherein the electronic device comprises a RAM device.

20. The method for repairing an electronic device with a fuse structure as claimed in claim 12, further comprising removing the lens overlying the conducting layers.
